(19) United States
(12) Patent Application Publication
(10) Pub. No.: US 2025/0347924 A1
(43) Pub. Date: Nov. 13, 2025

(54) Display System

(71) Applicant: 3M INNOVATIVE PROPERTIES COMPANY, St. Paul, MN (US)

(72) Inventors: John M. DeSutter, Maplewood, MN (US); Nicholas C. Erickson, St. Paul, MN (US); Stephen M. Menke, Eagan, MN (US); Robert L. Brott, Woodbury, MN (US); Caitlin M. Race, Stillwater, MN (US)

(21) Appl. No.: 19/099,317

(22) PCT Filed: Aug. 9, 2023
(86) PCT No.: PCT/IB2023/058062

§ 371 Date: Jan. 28, 2025

Related U.S. Application Data
(60) Provisional application No. 63/397,636, filed on Aug. 12, 2022.

(51) Int. Cl. G02B 27/42; G02B 5/18; G02B 27/44; H10K 59/80

(52) U.S. Cl. CPC G02B 27/4205; G02B 5/1819; G02B 5/1842; G02B 27/44; H10K 59/879; G02B 2005/1804

(57) ABSTRACT

A display system includes a display region configured to form an image thereacross for viewing by a viewer and including a light emitting region configured to emit light and a light non-emitting region not configured to emit light; and a light diffractive layer configured to be between the viewer and the display region and disposed substantially parallel to, and spaced apart along a thickness direction of the display system from, the display region. The light diffractive layer includes a light diffractive region configured to diffract light and a light non-diffractive region not configured to diffract light. The light diffractive and non-diffractive regions of the light diffractive layer are aligned, and substantially coextensive in length and width, with the respective light non-emitting and emitting regions of the display region.

### TECHNICAL FIELD

The present description relates generally to display systems.

### BACKGROUND

A display system can include an organic light emitting diode (OLED) display panel.

### SUMMARY

In some aspects, the present description provides a display system including a display region configured to form an image thereacross for viewing by a viewer and including a light emitting region configured to emit light and a light non-emitting region not configured to emit light; and a light diffractive layer configured to be between the viewer and the display region and disposed substantially parallel to, and spaced apart along a thickness direction of the display system from, the display region. The light diffractive layer includes a light diffractive region configured to diffract light and a light non-diffractive region not configured to diffract light. The light diffractive and non-diffractive regions of the light diffractive layer can be aligned, and substantially coextensive in length and width, with the respective light non-emitting and emitting regions of the display region.

In some aspects, the present description provides a display system including a plurality of light emitting pixels defining a plurality of first inter-pixel regions therebetween, each of the first inter-pixel regions devoid of any light emitting pixels; and a light diffractive layer disposed on, and spaced apart along a thickness direction of the display system from, the light emitting pixels and including a plurality of light diffractive regions substantially aligned and coextensive with the plurality of first inter-pixel regions in one-to-one correspondence. The light diffractive regions can include a plurality of substantially parallel linear diffractive elements extending along a same in-plane first direction and arranged along a same in-plane orthogonal second direction. Light emitted by the pixels is diffractively transmitted by the light diffractive layer and exits the display system in air toward a viewer. The exiting light and a comparative exiting light of a comparative display system that has a same construction except that it does not include the light diffractive layer, have respective intensity and comparative intensity profiles as a function of light propagation angle, such that in a first plane that is parallel to the thickness direction and orthogonal to the first direction and for at least one wavelength in a visible wavelength range extending from about 420 nm to about 680 nm: a peak intensity of the intensity profile is greater than a peak intensity of the comparative intensity profile by at least 10%; and a half width at half maximum (HWHM) of the intensity profile is smaller than a HWHM of the comparative intensity profile by at least 10 degrees.

In some aspects, the present description provides a display system including a plurality of light emitting pixels defining a plurality of first inter-pixel regions therebetween where each of the first inter-pixel regions devoid of any light emitting pixels; and a light diffractive layer disposed on, and spaced apart along a thickness direction of the display system from, the light emitting pixels and including a plurality of light diffractive regions substantially aligned and coextensive with the plurality of first inter-pixel regions in a one-to-one correspondence. The light diffractive regions can include a plurality of substantially parallel linear diffractive elements extending along a same in-plane first direction and arranged along a same in-plane orthogonal second direction. Light emitted by the pixels is diffractively transmitted by the light diffractive layer and exits the display system in air toward a viewer. The exiting light and a comparative exiting light of a comparative display system that has a same construction except that it does not include the light diffractive layer, have respective intensity and comparative intensity profiles as a function of light propagation angle, such that in a first plane that is parallel to the thickness and the first directions, for at least one wavelength in a visible wavelength range extending from about 420 nm to about 680 nm, and for each propagation angle in an angular range of from at most 10 degrees to at least 50 degrees, the intensity profile has a greater magnitude than the comparative intensity profile.

In some aspects, the present description provides a display system including one or more light emitting regions configured to emit light substantially co-planar with one or more light non-emitting regions not configured to emit light; and one or more light diffractive regions disposed on, and spaced apart along a thickness direction of the display system from, the one or more light non-emitting regions, such that in a top plan view, the one or more light diffractive regions cover more than 60% of the one or more light non-emitting regions and less than 40% of the one or more light emitting regions. At least some light obliquely emitted by the one or more light emitting regions exits the display system after being diffractively transmitted by the one or more light diffractive regions, such that in each of orthogonal first and second planes that are both parallel to the thickness direction, and for at least one wavelength in a visible wavelength range extending from about 420 nm to about 680 nm, a half width at half maximum (HWHM) of an intensity profile of the exiting light is smaller than a HWHM of a comparative intensity profile of a comparative display system that has a same construction except that it does not include the one or more light diffractive regions.

In some aspects, the present description provides a display system including one or more light emitting regions configured to emit light and one or more light non-emitting regions not configured to emit light and substantially co-planar with the one or more light emitting regions; and one or more light diffractive regions disposed on, and spaced apart along a thickness direction of the display system from, the one or more light non-emitting regions, such that in a top plan view, the one or more light diffractive regions cover more than 60% of the one or more light non-emitting regions and less than 40% of the one or more light emitting regions. At least some light obliquely emitted by the one or more light emitting regions exits the display system after being diffractively transmitted by the one or more light diffractive regions, such that in each plane of at least one plane parallel to the thickness direction, and for at least one wavelength in a visible wavelength range extending from about 420 nm to about 680 nm, a normalized intensity profile of the display system normalized with respect to a comparative intensity profile of a comparative display system that has a same construction except that it does not include the one or more light diffractive regions, includes a peak at a propagation angle of less than about 10 degrees and a global minimum disposed between the peak and a propagation angle of less than about 60 degrees.

In some aspects, the present description provides a display system including one or more light emitting regions configured to emit light and one or more light non-emitting regions not configured to emit light and substantially co-planar with the one or more light emitting regions; and one or more light diffractive regions disposed on, and spaced apart along a thickness direction of the display system from, the one or more light non-emitting regions, such that in a top plan view, the one or more light diffractive regions cover more than 60% of the one or more light non-emitting regions and less than 40% of the one or more light emitting regions. At least some light obliquely emitted by the one or more light emitting regions exits the display system after being diffractively transmitted by the one or more light diffractive regions, such that for substantially mutually orthogonal first and second planes that are parallel to the thickness direction, and for at least one wavelength in a visible wavelength range extending from about 420 nm to about 680 nm, a normalized intensity profile of the display system normalized with respect to a comparative intensity profile of a comparative display system that has a same construction except that it does not include the one or more light diffractive regions, includes: in the first plane, a global minimum at a propagation angle of less than about 60 degrees; and in the second plane, a magnitude of greater than about 1 for all propagation angles from about zero degrees to at least about 40 degrees.

These and other aspects will be apparent from the following detailed description. In no event, however, should this brief summary be construed to limit the claimable subject matter.

### BRIEF DESCRIPTION OF THE DRAWINGS

FIG. 1 is a schematic cross-sectional view of a display system, according to some embodiments.

FIG. 2 is a schematic cross-sectional view of at least a portion of a display system, according to some embodiments.

FIG. 3 is a schematic top plan view of a display system, according to some embodiments.

FIG. 4 is a schematic cross-sectional view of at least a portion of a display system that may correspond to the display system of FIG. 3, according to some embodiments.

FIGS. 5-6 are schematic cross-section views of pluralities of substantially parallel linear diffractive elements, according to some embodiments.

FIG. 7 is a schematic cross-sectional view of a display system including a light diffractive layer that includes a backfilled structured layer, according to some embodiments.

FIG. 8 is a schematic top plan view of a display system include pixels arranged on a square lattice, according to some embodiments.

FIGS. 9A-9B are schematic cross-sectional views of a display system and a corresponding comparative display system, respectively, according to some embodiments.

FIGS. 10-11 are plots of intensity as a function of light propagation angle for various display systems and corresponding comparative display systems, according to some embodiments.

FIG. 12 is a schematic illustration of a light diffractive layer and first and second planes that are both parallel to a thickness direction and make an angle α1 with each other, according to some embodiments.

FIGS. 13-15 are plots of normalized intensity of display systems as a function of light propagation angle in different planes, according to some embodiments

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

A display system can emit light along an axial direction towards a viewer and along off-axis directions. In some cases, it is desired that at least some of the off-axis light is redirected substantially along the axial direction to increase the axial intensity and the brightness experienced by the user. It has been found, according to some embodiments, that suitably patterned light diffractive layers described herein can be used to achieve this effect.

Diffraction gratings have been used with organic light emitting diode (OLED) displays for other purposes. A diffraction grating can be placed over an organic light emitting diode (OLED) display panel to correct off-axis color shift as described in U.S. Pat. No. 10,991,765 (Freier et al.), for example. Diffractive structures can be disposed on emissive regions of an OLED device within an evanescent zone of the emissive regions to improve extraction of light that would otherwise be trapped in the OLED device as described in U.S. Pat. Appl. Pub. No. 2010/0110551 (Lamansky et al.), for example. In each of these cases, a diffractive layer is placed over an entire emissive layer of the OLED device. It has been found that when a diffraction grating is placed over an entire emissive layer with the diffraction grating selected to provide a first order diffraction of at least some of the off-axis light into the axial direction, some of the light emitted by the pixels in the axial direction will be diffracted into off-axis directions so that the axial brightness is not substantially increased by redirecting the off-axis light.

According to some embodiments of the present description, it has been found that a light diffractive layer can be patterned to include light diffractive regions above light non-emitting regions but not above the light emitting regions (e.g., pixels) and this allows at least some of the off-axis light to be diffracted into the axial direction substantially without diffracting the emitted axial light into non-axial directions. It has been found, according to some embodiments, that this can result in significant improvement in axial intensity (e.g., by at least 10, 20, 30, 40, or even 50%) compared to a comparative display system that does not include the diffractive layer and/or compared to a display system that includes a diffractive layer with diffractive structures covering the entire display panel.

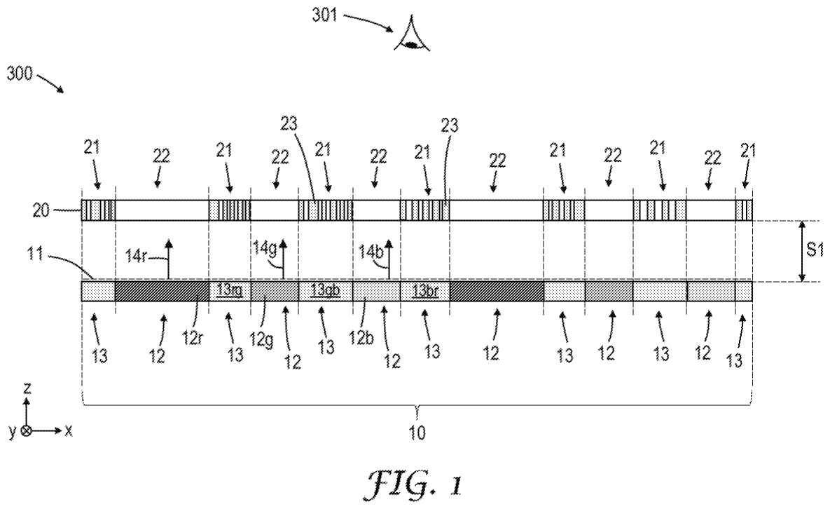

FIG. 1 is a schematic cross-sectional view of a display system 300, according to some embodiments. In some embodiments, the display system 300 includes a display region 10 configured to form an image 11 thereacross for viewing by a viewer 301 and including a light emitting region 12 configured to emit light (e.g., 14b, 14g, 14r) and a light non-emitting region 13 not configured to emit light; and a light diffractive layer 20 configured to be between the viewer 301 and the display region 10 and disposed substantially parallel (e.g., within 30, 20, 10, or 5 degrees of parallel) to, and spaced apart along a thickness direction (z-direction) of the display system 300 from, the display region 10. The light diffractive layer 20 can include a light diffractive region 21 configured to diffract light and a light non-diffractive region 22 not configured to diffract light. In some embodiments, the light diffractive and non-diffractive regions 21 and 22 of the light diffractive layer 20 are aligned, and substantially coextensive in length (x-axis) and width (y-axis), with the respective light non-emitting and emitting regions 13 and 12 of the display region 10. The emitted light 14b, 14g, 14r can include wavelengths in a visible wavelength range extending from about 420 nm to about 680 nm. For example, emitted light 14b can be blue light in a wavelength range of about 420 nm to about 490 nm, emitted light 14g can be green light in a wavelength range of about 490 nm to about 590 nm, and emitted light 14r can be red light in a wavelength range of about 590 nm to about 680 nm.

Layers or elements can be described as substantially coextensive with each other in length and width if greater than 50% of the length and width of each layer or element is coextensive with greater than 50% of the length and width of each other layer or element. In some embodiments, for layers or elements described as substantially coextensive with each other in length and width, at least about 60%, or at least about 70%, or at least about 80%, or at least about 90%, or at least about 95% of each layer or element is coextensive in length and width with at least about 60%, or at least about 70%, or at least about 80%, or at least about 90%, or at least about 95% of the length and width of each other layer or element.

In some embodiments, at least 30%, or 35%, or 40%, or 45%, or 50%, or 55%, or 60%, or 65%, or 70%, or 75%, or 80%, or 85%, or 90%, or 95% of a total area of the light diffractive region of the light diffractive layer overlaps at least 30%, or 35%, or 40%, or 45%, or 50%, or 55%, or 60%, or 65%, or 70%, or 75%, or 80%, or 85%, or 90%, or 95% of a total area of the light non-emitting region of the display region. For example, in some embodiments, at least 50% of a total area of the light diffractive region of the light diffractive layer overlaps at least 50% of a total area of the light non-emitting region of the display region, or at least 75% of a total area of the light diffractive region of the light diffractive layer overlaps at least 75% of a total area of the light non-emitting region of the display region, or at least 90% of a total area of the light diffractive region of the light diffractive layer overlaps at least 80% of a total area of the light non-emitting region of the display region. In some embodiments, at least 30%, or 35%, or 40%, or 45%, or 50%, or 55%, or 60%, or 65%, or 70%, or 75%, or 80%, or 85%, or 90%, or 95% of a total area of the light non-diffractive region of the light diffractive layer overlaps at least 30%, or 35%, or 40%, or 45%, or 50%, or 55%, or 60%, or 65%, or 70%, or 75%, or 80%, or 85%, or 90%, or 95% of a total area of the light emitting region of the display region. For example, in some embodiments, at least 50% of a total area of the light non-diffractive region of the light diffractive layer overlaps at least 50% of a total area of the light emitting region of the display region, or at least 75% of a total area of the light non-diffractive region of the light diffractive layer overlaps at least 75% of a total area of the light emitting region of the display region, or at least 90% of a total area of the light non-diffractive region of the light diffractive layer overlaps at least 80% of a total area of the light emitting region of the display region.

In some embodiments, an average spacing S1 between the light diffractive layer 20 and the display region 10 is greater than about 10, or 15, or 20, or 30, or 40, or 50, or 100, or 150, or 200, or 250, or 300, or 350, or 400, or 400, or 500 microns and less than about 5000, or 4500, or 4000, or 3500, or 3000, or 2500, or 2000, or 1500, or 1000 microns. In some embodiments, the average spacing S1 is in a range of about 10 microns to about 5000 microns, or about 20 microns to about 4000 microns, or about 30 microns to about 2000 microns, for example.

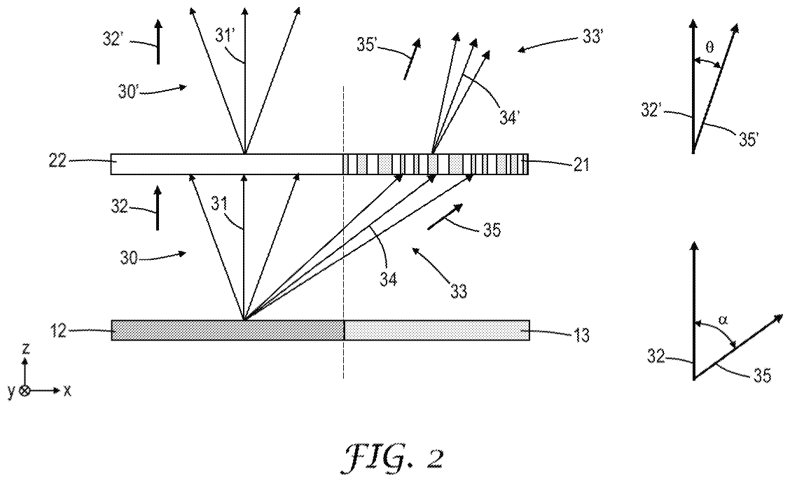

FIG. 2 is a schematic cross-sectional view of at least a portion of a display system (e.g., display system 300, or display system 305 or 310 described elsewhere herein), according to some embodiments. In some embodiments, the light emitting region 12 is configured to emit an emitted first cone 30 of light and an emitted second cone 33 of light. The emitted first and second cones 30 and 33 of light are incident on the light diffractive layer in a range of angles that can depend on the spacing S1 (see, e.g., FIG. 1) and the origin of the cones of light. The light diffractive region 21 can diffract at least a portion of the light in the second cone 33 incident on the light diffractive region 21 in a range of directions into a range of diffracted directions (e.g., given by the diffraction grating equation). The emitted first cone 30 of light includes an emitted first central light ray 31 propagating along an emitted first direction 32. The emitted first cone 30 of light is incident on the non-diffractive (22), but not the diffractive (21), region of the light diffractive layer and at least a portion of the emitted first cone 30 of light is transmitted by the non-diffractive region 22 of the light diffractive layer as a transmitted first cone 30′ of light having a transmitted first central light ray 31′ propagating along a transmitted first direction 32′ within about 10, or 8, or 6, or 4, or 2, or 1 degrees of the emitted first direction 32. The emitted second cone of light 33 includes an emitted second central light ray 34 propagating along an emitted second direction 35 making an angle α of greater than about 10, or 15, or 20, or 25, or 30 degrees with the emitted first direction 32. The emitted second cone 33 of light is incident on the diffractive (21), but not the non-diffractive (22), region of the light diffractive layer and at least a portion of the emitted second cone 33 of light is diffractively transmitted by the diffractive region 21 of the light diffractive layer as a diffracted second cone 33′ of light having a diffracted second central light ray 34′ propagating along a diffracted second direction 35′ making an angle θ of less than about 10, or 8, or 6, or 4, or 2, or 1 degrees with the emitted first direction 32. In some embodiments, at least 50%, or 60%, or 70%, or 80%, or 90% of the emitted first cone 30 of light is transmitted by the non-diffractive region 22 of the light diffractive layer. In some embodiments, at least 5%, or 10%, or 15%, or 20%, or 25%, or 30%, or 35%, or 40%, or 45%, or 50% of the emitted second cone 33 of light is diffractively transmitted by the diffractive region 21 of the light diffractive layer.

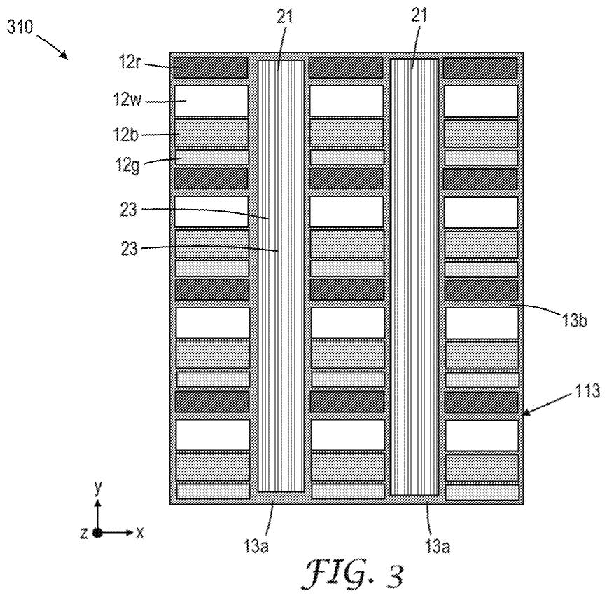

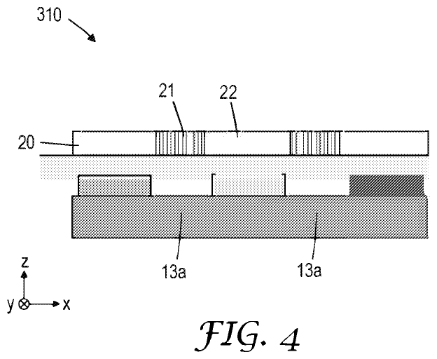

FIG. 3 is a schematic top view of a display system 310, according to some embodiments. FIG. 4 is a schematic cross-sectional view of at least a portion of the display system 310, according to some embodiments. Display system 310 may correspond to display system 300, except that at least in the embodiment illustrated in FIG. 3, display system 310 includes optional light emitting pixels 12w (e.g., white pixels) in addition to light emitting pixels 12b, 12g, and 12r (e.g., blue, green, and red pixels) and the pixels in the different embodiments may have different arrangements. In some embodiments, the light emitting region 12 includes a plurality of spaced apart light emissive pixels (e.g., 12b, 12g, 12r and optionally 12w), and regions (e.g., 13b or 13rg, 13gb, 13br schematically illustrated in FIG. 1, for example) between the emissive pixels include the light non-emitting region 13. In some embodiments, the regions (e.g., 13a, 13b) between the emissive pixels are interconnected to form a continuous light non-emitting region 113. The light emissive pixels can be arranged as schematically illustrated in FIG. 3, for example, or can have any other suitable arrangement as would be appreciated by those of ordinary skill in the art.

In some embodiments, a display system 300, 310 includes a plurality of light emitting pixels (e.g., 12 or 12b, 12g, 12r, 12w) defining a plurality of first inter-pixel regions 13a therebetween where each of the first inter-pixel regions 13a is devoid of any light emitting pixels In some embodiments, the plurality of light emitting pixels define a plurality of second inter-pixel regions 13b therebetween, where each of the second inter-pixel regions is devoid of any light emitting pixels and has an area that is less than an area of each of the first inter-pixel regions 13a by at least a factor of 2, or 5, or 10, or 20, or 30, or 40, or 50, or 100. For example, the pixels can be arranged into rows where inter-pixels regions (e.g., 13a) between the rows have a substantially larger total area than inter-pixels regions (e.g., 13b) between pixels within the rows. The light diffractive regions 21 can be substantially coextensive in length and width with the inter-pixel regions between the rows.

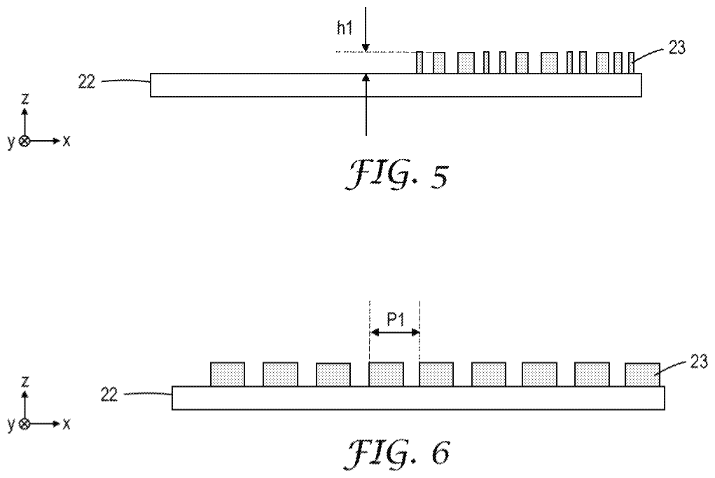

In some embodiments, the light diffractive region 21 includes a plurality of substantially parallel linear diffractive elements 23 extending along a same in-plane first direction (y-direction) and arranged along a same in-plane orthogonal second direction (x-direction). FIGS. 5-6 are schematic cross-section views of pluralities of substantially parallel linear diffractive elements 23, according to some embodiments. In some embodiments, the plurality of substantially parallel linear diffractive elements 23 form an irregular pattern along the second direction (as schematically illustrated in FIG. 5, for example). In some embodiments, the plurality of substantially parallel linear diffractive elements 23 form a periodic pattern along the second direction (as schematically illustrated in FIG. 6, for example). As is known in the art, the geometry of a grating and the refractive index difference across the grating can be selected to provide a desired first order diffraction peak in a desired direction. In some embodiments, the periodic pattern has a period P1 in a range from about 0.2 to about 5 microns, or about 0.3 to about 3.5 microns, or about 0.4 to about 3 microns, or from about 0.5 to about 2.5 microns, or from about 0.6 to about 2 microns. In some embodiments, the linear diffractive elements 23 form an irregular pattern having an average spacing or pitch in any of the ranges described for P1. In some embodiments, the plurality of substantially parallel linear diffractive elements 23 has an average height h1 in a range from about 0.05 to about 3.5 microns, or about 0.1 to about 3.25 microns, or about 0.2 to about 3 microns, or about 0.3 to about 2.75 microns, or about 0.4 to about 2.5 microns, or from about 0.5 to about 2.25 microns, or from about 0.6 to about 2 microns, or from about 0.7 to about 1.75 microns, or from about 0.8 to about 1.5 microns, or from about 0.8 to about 1.25 microns, or from about 0.8 to about 1 microns.

As is known in the art, light diffractive structures of a light diffractive layer can be selected to deflect light into desired directions when the light is transmitted through the light diffractive layer. The light diffractive region 21 can include any suitable diffractive structures that result in light diffraction into suitable directions. For example, the light diffractive region 21 can include phase gratings, amplitude gratings, one-dimensional gratings (e.g., including substantially parallel linear diffractive elements 23), two-dimensional gratings (e.g., on a square, rectangular, or hexagonal lattice), subwavelength structures, metasurface structures, and/or other diffractive structures known in the art. In some embodiments, the light diffractive structures form a grating, and the geometry and refractive indices of the light diffractive structures can be related to the desired directions by a diffraction grating equation, for example. Illustrative diffractive structures described by diffraction grating equations can be found in “Design and fabrication of binary slanted surface-relief gratings for a planar optical interconnection”, Miller et al., Applied Optics, Vol. 36, No. 23, 1997 and “Formulation for stable and efficient implementation of the rigorous coupled-wave analysis of binary gratings”, Moharam et al., J. Opt. Soc. Am. A, Vol. 12, No. 5, 1995, for example. In some embodiments, the light diffractive structures form a metasurface (which can be considered to be a diffractive surface) that provides suitable steering into desired directions. Illustrative metasurfaces for beam steering are described in U.S. Pat. Appl. Publ. No., 2021/0109364 (Aieta et al.) and “Free-Form Diffractive Metagrating Design Based on Generative Adversarial Networks”, Jiang et al., ACS Nano, 13, 8872-8878, 2019, for example. The geometry of the diffractive elements can be selected, in part, based on the geometry of the pixel layout. For example, when pixels are arranged into rows (see, e.g., FIG. 2), substantially parallel linear diffractive elements 23 extending along regions between the rows may be preferred, while when pixels are arranged in a pentile or rectangular grid arrangement, a two-dimensional grating may be preferred.

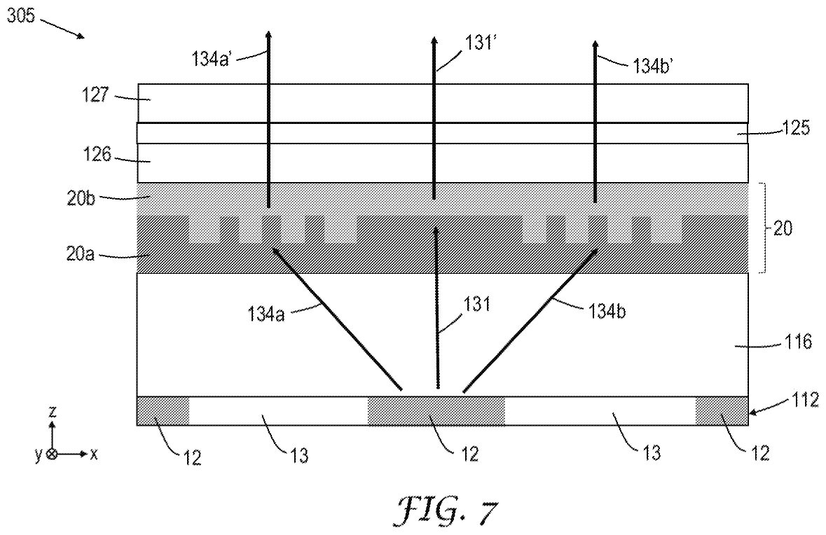

FIG. 7 is a schematic cross-sectional view of a display system 305, according to some embodiments. The display system 305, which may correspond to display system 300 or 310, for example, includes a pixelated layer 112, a light diffractive layer 20, and a layer 116 disposed on pixelated layer 112 between the light diffractive layer 20 and the pixelated layer 112. The layer 116 can be a (e.g., thin film) encapsulant layer and/or an (e.g., optically clear) adhesive layer, or a glass layer or another display layer such as a polarizer or touch sensor layer, for example. The pixelated layer 112 includes light emitting regions 12 and light non-emitting regions 13. The pixelated layer 112 can be any suitable pixelated layer. In some embodiments, the pixelated layer 112 includes the organic emissive materials of an organic light emitting diode (OLED) display panel, for example. In some embodiments, the pixelated layer 112 is a layer of a micro-OLED display, for example. In other embodiments, the pixelated layer 112 is a layer of an inorganic μLED (micro-light emitting diode) display, for example. It should be understood that the light diffractive structures of the light diffractive layer 20 can have length scales substantially smaller than schematically illustrated in FIG. 7.

The light diffractive layer can include first and second layers 20a and 20b. In some embodiments, the first layer 20a is formed on layer 116 (or formed on another layer and then laminated to layer 116) using a cast and cure process where diffractive structures are fabricated from a tool by casting a polymerizable resin composition onto layer 116 (or another layer) and curing the resin in contact with a structured surface of the tool. Such cast and cure methods are described in U.S. Pat. No. 5,175,030 (Lu et al.) and U.S. Pat. No. 5,183,597 (Lu) and in U.S. Pat. Appl. Pub. No. 2012/0064296 (Walker, J R. et al.), for example. The structured surface of the tool can be selected to define light diffractive regions and light non-diffractive regions, or the tool can define light diffraction structures throughout the structured surface of the first layer 20a and then portions of the light diffractive structures can be filled in in a subsequent coating step with a same material as used to form the first layer 20a in the cast and cure process, or a different material with a similar refractive index (e.g., substantially closer in refractive index to the cast and cure material than to the material of the second layer 20b), in order to define light non-diffractive regions. The second layer 20b can be a (e.g., planarizing) backfill layer coated over the structured surface defined in first layer 20a. The first and second layers 20a and 20b typically have different refractive indices na and nb, respectively, for at least a same first wavelength (e.g., about 550 nm) in a wavelength range of 420 nm to 680 nm, for example. In some embodiments, the difference nb−na can be at least about 0.03, 0.05, 0.07, 0.09, or 0.1 for example, for at least the first wavelength. In some such embodiments, or in other embodiments, the difference nb−na can be up to about 2, 1.5, 1, 0.8, 0.6, 0.5, or 0.4, for example, for at least the first wavelength. In some embodiments, the non-diffractive regions include a structured interface and the difference in refractive index across the structured interface can be less than about 0.08, 0.06, 0.05, 0.04, 0.03, 0.02, or 0.01, for example, for at least the first wavelength. In some embodiments, the diffractive layer 20 includes more than 2 materials or layers. For example, the diffractive layer 20 can include a thin (e.g., substantially thinner than the grating height) overcoat layer at the grating interface that may have a high refractive index (e.g., the refractive index can be at least about 2, such as a refractive index of about 2.5, for example) for at least the first wavelength. In some embodiments, at the first wavelength, the layer 20a has a refractive index of about 1.4 to about 1.55, and the layer 20b has a refractive index of about 1.75 to about 1.85. The layer 116 can have a thickness of about 20 to 1000 microns, the layer 20a can have a thickness of about 10 to 20 microns, and the layer 20b can have a thickness of about 5 to about 15 microns, for example. The thickness of the layer 116 may be in a range of about 20 to about 30 microns in cell phone applications, for example, and may be in a range of about 500 to about 1000 microns in television applications, for example. In some embodiments, the light diffractive layer 20 is formed separately and then disposed on the emissive layer with an optional air gap therebetween or the light diffractive layer 20 can be laminated to the emissive layer.

The light diffractive and light non-diffractive regions can be patterned by any other suitable means. In some embodiments, the light diffractive and light non-diffractive regions can be patterned by inkjet printing, photolithography, masking, or other suitable patterning technologies. In some embodiments, the patterning technology determines the placement of an index matching (e.g., difference in refractive index less than about 0.08, 0.06, 0.05, 0.04, 0.03, 0.02, or 0.01, for example) material to define the location of the light non-diffractive region. In some embodiments, the patterning technology determines the placement of an index mis-matching (e.g., difference in refractive index at least about 0.03, 0.05, 0.07, 0.09, or 0.1 for example) material to define the light diffractive regions. In some embodiments, the patterning technology defines the exposure region over which the grating is preferentially fabricated or removed by, for example, etching or scribing. In some embodiments, the light diffractive layer can be formed on the surface of another layer already present in the display system by etching or scribing where the process of etching or scribing is patterned as to define the light diffractive and light non-diffractive regions. Other methods of patterning know in the art may alternatively be utilized.

At least a portion 131′ of light 131 is transmitted through a light non-diffractive region of light diffractive layer 20 in a direction (e.g., z-direction) substantially normal (e.g., within 30, 20, 10, or 5 degrees of normal) to a plane (xy-plane) of the emissive layer 112, while at least portions 134a′ and 134b′ of respective light 134a and 134b are transmitted through light diffractive regions of the light diffractive layer and are diffracted into directions closer to the direction (z-direction) substantially normal to the plane (xy-plane) of the emissive layer 112. Light 131′ can correspond to light in the transmitted cone of light 30′ while light 134a′, 134b′ can correspond to light in the diffracted cone of light 33′, for example.

The display system 305 may further include a circular polarizer 125 disposed on the light diffractive layer 20. The circular polarizer 125 can be included to reduce reflection from an OLED display panel including the emissive layer 112, for example. The circular polarizer 125 can be a combination of a linear absorptive polarizer and a quarter wave retarder, for example. The circular polarizer 125 can be disposed between first and second layers 126 and 127, where first layer 126 can be or include an adhesive layer bonding the circular polarizer 125 to the light diffractive layer 20. The second layer 127 can be a protective layer disposed on the circular polarizer 125 opposite the first layer 126.

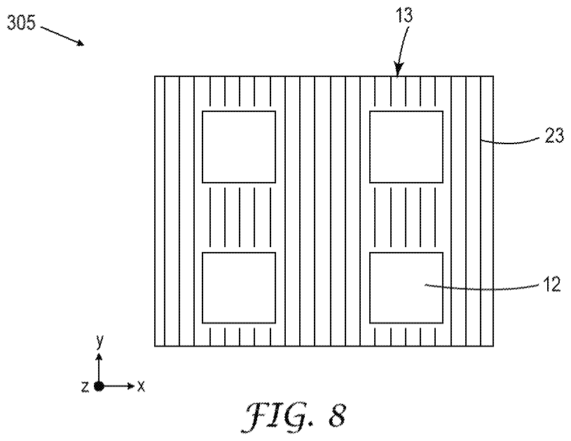

FIG. 8 is a schematic top plan view of display system 305 schematically showing the diffractive layer including diffractive elements 23 disposed over two-dimensional array of pixels 12, according to some embodiments. In other embodiments, the pixels 12 have a different arrangement (see, e.g., FIG. 3).

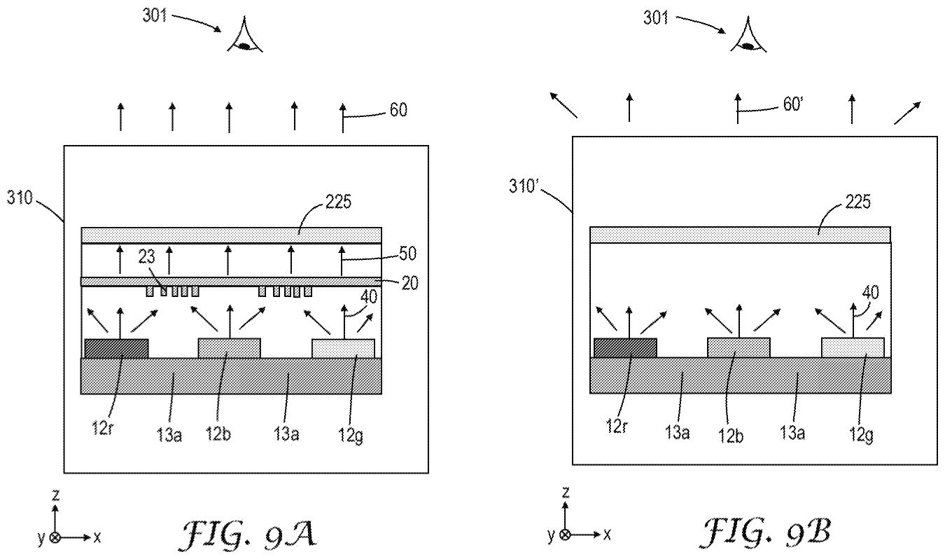

FIG. 9A is a schematic cross-sectional view of a display system 310 including a light diffractive layer 20, according to some embodiments. FIG. 9B is a schematic cross-sectional view of a comparative display system 310′ that has a same construction as the display system 310 except that it does not include the light diffractive layer 20. In general, a comparative display system refers to a display system that does not include the light diffractive layer 20 and/or that does not include the light diffractive regions 21, but that otherwise has a same construction as that of the display system. The display system 310, 310′ can include an outer layer 225 which can include one or more of a circular polarizer, a touch panel, or a protective cover layer. Other layers commonly used in displays (e.g., color filters and/or down conversion layers) can optionally be present above or below the light diffractive layer 20 in the display system 310 and at a corresponding location in the comparative display system 310′.

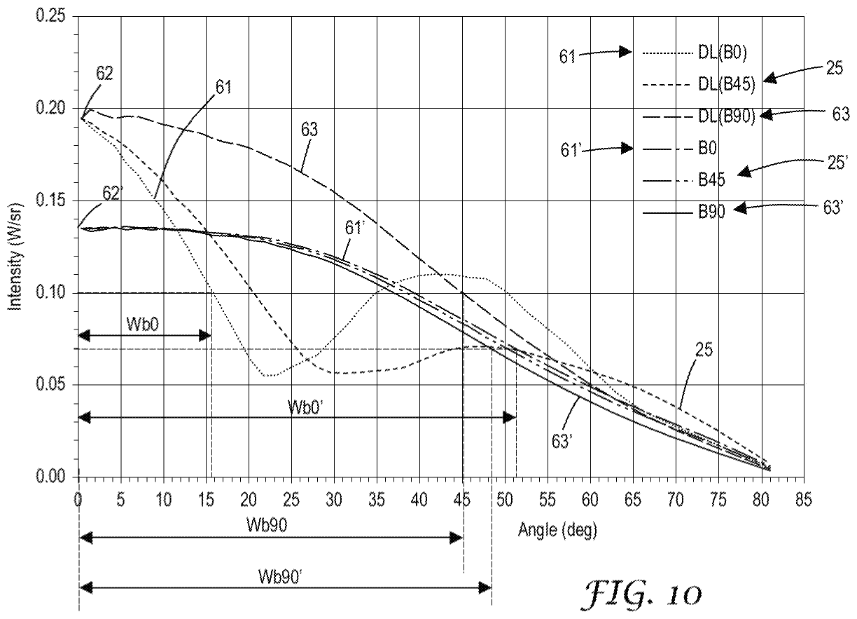

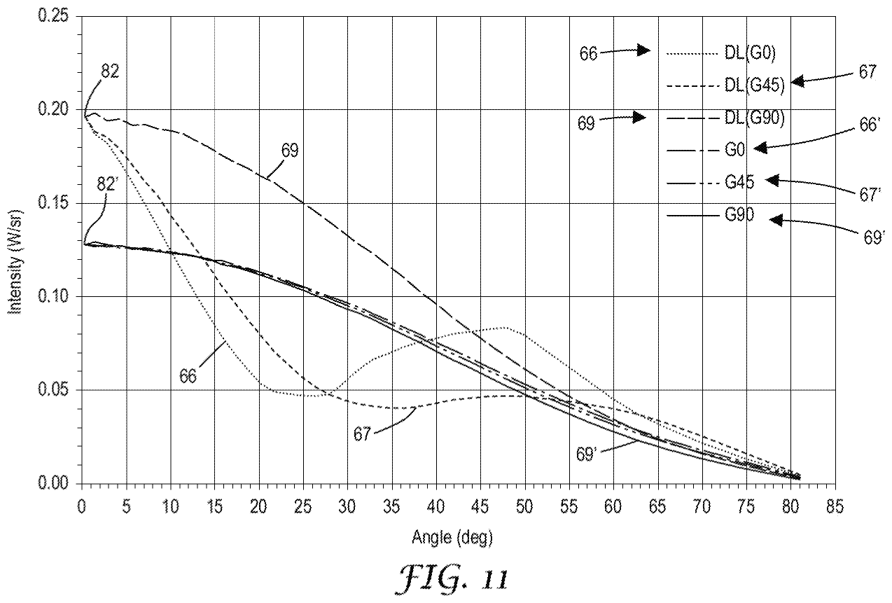

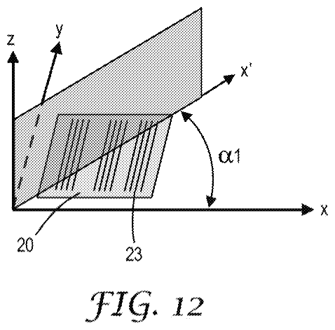

FIGS. 10-11 are plots of intensity as a function of light propagation angle in air (angle between a light propagation direction and a normal to the display) for various display systems and corresponding comparative display systems, according to some embodiments. The angle can be defined in various planes such as the xz-plane, the yz-plane, and/or a plane making an angle for about 45 degrees, for example, with the xz- and yz-planes. The embodiment of FIGS. 10-11 corresponds to the embodiment schematically illustrated in FIG. 3. The plots in FIGS. 10-11 are for light from blue and green pixels, respectively. FIG. 12 is a schematic illustration of a light diffractive layer 20, according to some embodiments, and first (xz-plane) and second (x′z-plane) planes that are both parallel to the thickness direction (z-direction) and make an angle α1 with each other. The angle α1 may be at least about 30, 35, 40, or 45 degrees. The angle α1 should be understood to be the smallest angle between the first and second planes so that the angle is not greater than 90 degrees. The angle α1 may be no more than about 70, 60, 50, 40, or 45 degrees. The angle α1 can be about 45 degrees, for example. The exiting light 60 of the display system 310 (see, e.g., FIG. 9A) and the comparative exiting light 60′ of the comparative display system 310′ that has a same construction except that it does not include the light diffractive layer 20 (see, e.g., FIG. 9B), have respective intensity profile (e.g., 61, 63, 25 illustrated in FIG. 10 or 66, 69, 67 illustrated of FIG. 11) and comparative intensity profile (e.g., 61′, 63′, 25′ illustrated in FIG. 10 or 66′, 69′, 67′ illustrated in FIG. 11) as a function of the light propagation angle. For each of the curves in these figures the angle is in a plane parallel to the thickness direction (z-direction) making an angle indicated in the figure legend (0, 45, or 90 degrees) relative to a first in-plane direction which can be a direction along which the diffractive elements 23 are arranged (e.g., x-direction).

In some embodiments, a display system 300, 305, 310 includes a plurality of light emitting pixels (e.g., 12 or 12b, 12g, 12r, 12w) defining a plurality of first inter-pixel regions 13a therebetween where each of the first inter-pixel regions 13a is devoid of any light emitting pixels; and a light diffractive layer 20 disposed on, and spaced apart along a thickness direction (z-direction) of the display system from, the light emitting pixels and including a plurality of light diffractive regions 21 substantially aligned and coextensive with the plurality of first inter-pixel regions 13a in a one-to-one correspondence. In some embodiments, the light diffractive regions 21 include a plurality of substantially parallel linear diffractive elements 23 extending along a same in-plane first direction (y-direction) and arranged along a same in-plane orthogonal second direction (x-direction). In some embodiments (see, e.g., FIGS. 9A-9B), light emitted (e.g., emitted light 40) by the pixels is diffractively transmitted (e.g., diffractively transmitted light 50) by the light diffractive layer and exits (e.g., exiting light 60) the display system in air toward a viewer 301, where the exiting light 60 and a comparative exiting light 60′ of a comparative display system 310′ that has a same construction except that it does not include the light diffractive layer 20, have respective intensity (61, 63) and comparative intensity (61′, 63′) profiles as a function of light propagation angle, such that in a first plane (e.g., xz-plane) that is parallel to the thickness direction and orthogonal to the first direction and for at least one wavelength (e.g., blue, red and/or green wavelength(s)) in a visible wavelength range extending from about 420 nm to about 680 nm: a peak intensity 62 of the intensity profile 61 is greater than a peak intensity 62′ of the comparative intensity profile 61′ by at least 10%; and a half width at half maximum (HWHM) Wb0 of the intensity profile 61 is smaller than a HWHM Wb0′ of the comparative intensity profile 61′ by at least 10 degrees. In some such embodiments, or in other embodiments, the peak intensity 62 of the intensity profile 61 is greater than the peak intensity 62′ of the comparative intensity profile 61′ by at least 15%, or 20%, or 30%, or 35%, or 40%, or 45%. In some such embodiments, or in other embodiments, the half width at half maximum (HWHM) Wb0 of the intensity profile 61 is smaller than a HWHM Wb0′ of the comparative intensity profile 61′ by at least 15, or 20, or 25, or 30, or 35 degrees. In some such embodiments, or in other embodiments, Wb0 is in a range of 10 degrees to 25 degrees and Wb0′ is in a range of 30 degrees to 60 degrees, or Wb0 is in a range of 12 degrees to 20 degrees and Wb0′ is in a range of 40 degrees to 50 degrees. The at least one wavelength can be or include a wavelength of about 550 nm, for example.

In some embodiments, in a second plane (e.g., yz-plane) that is parallel to the thickness and the first directions and for the at least one wavelength (e.g., blue, red and/or green wavelength(s)), a HWHM Wb90 of the intensity profile 63 is smaller than a HWHM Wb90′ of the comparative intensity profile 63′. In some embodiments, the HWHM Wb90 is smaller than the HWHM Wb90′ by at least 1, or 2, or 3 degrees. In some such embodiments, or in other embodiments, the HWHM Wb90 is in a range of 40 to 50 degrees and the HWHM Wb90′ is in a range of 40 to 60 degrees or 43 to 55 degrees. In some embodiments, it may be desired that Wb0 and Wb90 are smaller than Wb0′ and Wb90′, respectively, as this can correspond to collimation in vertical and horizontal directions which may be desired in hand-held displays, for example. In some embodiments, Wb0 is smaller than Wb0′, and Wb90 and Wb90′ are approximately equal (e.g., within 20, 15, 10, or 5 percent of equal). This may be desired in some cases as it can correspond to collimation in a vertical direction but little or no collimation in a horizontal direction which may be desired in television applications, for example. In some embodiments, substantially parallel linear diffractive elements 23 are utilized to provide Wb90 and Wb90′ that are approximately equal while two-dimensional patterns of diffractive elements are used to provide Wb90 substantially smaller than Wb90′

In some embodiments, a display system 300, 305, 310 includes a plurality of light emitting pixels (e.g., 12 or 12b, 12g, 12r, 12w) defining a plurality of first inter-pixel regions (e.g., 13 or 13a) therebetween where each of the first inter-pixel regions is devoid of any light emitting pixels; and a light diffractive layer 20 disposed on, and spaced apart along a thickness direction (z-axis) of the display system from, the light emitting pixels and including a plurality of light diffractive regions 21 substantially aligned and coextensive with the plurality of first inter-pixel regions in a one-to-one correspondence. The light diffractive regions 21 include a plurality of substantially parallel linear diffractive elements 23 extending along a same in-plane first direction (e.g., y-direction) and arranged along a same in-plane orthogonal second direction (e.g., x-direction). The diffractive elements 23 can have any of the geometries described elsewhere herein and/or can be arranged in any of the patterns describe elsewhere herein. In some embodiments (see, e.g., FIGS. 9A-9B), light emitted (e.g., emitted light 40) by the pixels is diffractively transmitted (e.g., diffractively transmitted light 50) by the light diffractive layer 20 and exits (e.g., exiting light 60) the display system in air toward a viewer 301. The exiting light 60 and a comparative exiting light 60′ of a comparative display system 310′ that has a same construction except that it does not include the light diffractive layer 20, have respective intensity (e.g., 63, 69) and comparative intensity (e.g., 63′, 69′) profiles as a function of light propagation angle, such that in a first plane (e.g., yz-plane) that is parallel to the thickness and the first directions, for at least one wavelength (e.g., blue, red and/or green wavelength(s)) in a visible wavelength range extending from about 420 nm to about 680 nm, and for each propagation angle in an angular range of from at most 10 degrees to at least 50 degrees, the intensity profile has a greater magnitude than the comparative intensity profile. In some embodiments, the angular range is from at most 10, 8, 6, 4, 2, 1 or 0.5 degrees. In some such embodiments, or in other embodiments, the angular range is to at least 50, 55, 60, 65, 70, 75, or 80 degrees. For example, the angular range can be from 10 to 50 degrees, or from 8 to 55 degrees, or from 6 to 60 degrees, or from 4 to 70 degrees. In some embodiments, the intensity profile has a greater magnitude than the comparative intensity profile by at least 5, 10, 15, 20, or 25 percent for each same propagation angle in the angular range.

In some embodiments, a display system 310, 305, 310 includes one or more light emitting regions 12 configured to emit light (e.g., 14b, 14g, 14r) with one or more light non-emitting regions 13 not configured to emit light; and one or more light diffractive regions 21 disposed on, and spaced apart along a thickness direction (z-direction) of the display system from, the one or more light non-emitting regions 13. In some embodiments, the one or more light diffractive regions 21 is substantially aligned and coextensive with the one or more light non-emitting regions 13 (which may be or include a plurality of first inter-pixel regions). For example, in some embodiments, in a top plan view (e.g., along z-axis), the one or more light diffractive regions 21 cover more than 60% of the one or more light non-emitting regions 13 and less than 40% of the one or more light emitting regions 12. In some embodiments, in the top plan view, the one or more light diffractive regions 21 cover more than 65%, or 70%, or 75%, or 80%, or 85%, or 90%, or 95% of the one or more light non-emitting regions 13. In some embodiments, in the top plan view, the one or more light diffractive regions 21 cover less than 40%, or 35%, or 30%, or 25%, or 20%, or 15%, or 10%, or 5% of the one or more light emitting regions 12. The one or more light non-emitting regions 13 and the one or more light emitting regions 12 can be substantially co-planar (e.g., xy-plane). For example, the one or more light non-emitting regions 13 and the one or more light emitting regions 12 can be in a same plane or nominally in a same plane or in a same plane up to deviations small compared to a total length and width (e.g., along x- and y-directions) of the display. In some embodiments, at least some light obliquely emitted (e.g., 33, 34, 134a, 134b; see, e.g., FIGS. 2 and 7) by the one or more light emitting regions exits (e.g., exiting light 33′, 34′, 134a′, 134b′) the display system 300, 305, 310 after being diffractively transmitted (e.g., diffractively transmitted light 50; see, e.g., FIG. 9A) by the one or more light diffractive regions 21.

In some embodiments, the display system 300, 305, 310 is such that in each of orthogonal first (e.g., xz-plane) and second (e.g., yz-plane) planes that are both parallel to the thickness direction (z-direction), and for at least one wavelength (e.g., blue, red and/or green wavelength(s)) in a visible wavelength range extending from about 420 nm to about 680 nm, a half width at half maximum (HWHM) (Wb0, Wb90) of an intensity profile (61, 63) of the exiting light is smaller than a HWHM (Wb0′, Wb90′) of a comparative intensity profile (61′, 63′) of a comparative display system 310′ that has a same construction except that it does not include the one or more light diffractive regions. In some embodiments, Wb0′-Wb0 is at least 10, 20, or 25 degrees. Wb0′-Wb0 can be up to about 60, 55, or 50 degrees, for example. In some embodiments, Wb90′-Wb90 is at least 1, 2, 2.5, or 3 degrees. Wb90′-Wb90 can be up to about 15, 10, or 5 degrees, for example. In some embodiments, Wb0 is smaller than Wb0′, and Wb90 and Wb90′ are approximately equal. In some embodiments, |Wb90′-Wb90| is less than about 15, 10, or 5 degrees. In some embodiments, the one or more light diffractive regions 21 includes a plurality of substantially parallel linear diffractive elements 23 extending along a same in-plane first direction (e.g., y-direction) and arranged along a same in-plane orthogonal second direction (e.g., x-direction) where the first and second planes are substantially orthogonal (e.g., within 30, 20, 10, or 5 degrees of orthogonal) to the respective first and second directions.

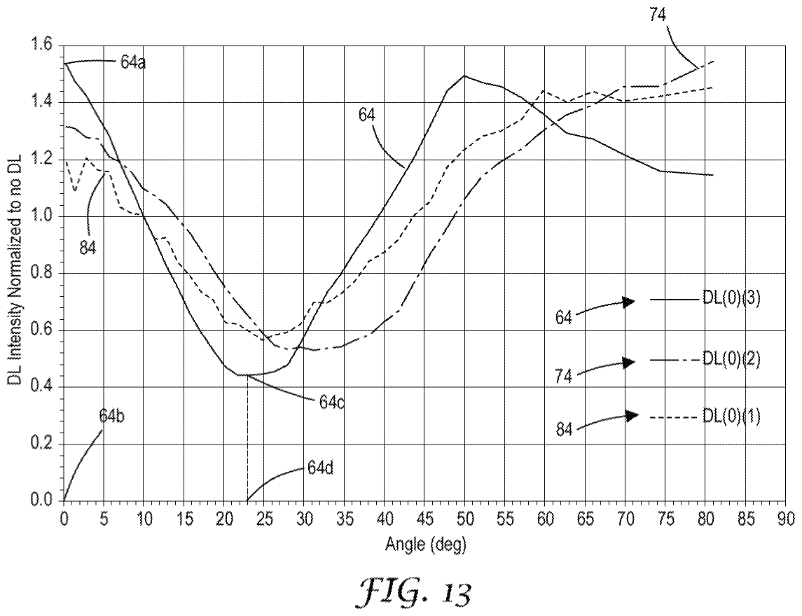

FIGS. 13-15 are plots of normalized intensity of display systems as a function of light propagation angle in air in different planes (e.g., those schematically illustrated in FIG. 12), according to some embodiments, where the normalized intensity is normalized with respect to comparative intensities of corresponding comparative display systems. For example, the normalized intensity can be determined at each given angle by dividing the intensity of the display system at that angle by the comparative intensity of the comparative display system at that same angle. The normalized intensities 64, 65, and 68 (and similarly, 74, 75, 78 and 84, 85, 88) are in planes making an angle of 0, 45, and 90 degrees, respectively, relative to a first in-plane direction which can be a direction along which the diffractive elements 23 are arranged (e.g., x-direction). The normalized intensities 64, 74, and 84 (and corresponding intensities in different planes) are for different embodiments. The normalized intensity 64, 65, 68 corresponds to the embodiment of FIG. 11. The normalized intensity 74, 75, 78 corresponds to an embodiment where the pixels are arranged on a square lattice (see, e.g., FIG. 8) with a 40 micron pitch and a pixel sized of 20 micron square and the grating pattern covers regions between the pixels. The grating pattern had a pitch P1 (see, e.g., FIG. 6) of 1200 nm. The normalized intensity 84, 85, 88 corresponds to a single 20 micron square pixel with the grating patten forming a 10 micron frame around the pixel.

In some embodiments, the display system 300, 305, 310 is such that such that in each plane of at least one plane parallel to the thickness direction (z-direction), and for at least one wavelength (e.g., blue, red, and/or green wavelength(s)) in a visible wavelength range extending from about 420 nm to about 680 nm, a normalized intensity profile (64, 65) of the display system normalized with respect to a comparative intensity profile (66′, 67′) of a comparative display system 310′ that has a same construction except that it does not include the one or more light diffractive regions, includes a peak (64a, 65a) at a propagation angle (64b, 65b) of less than about 10 degrees and a global minimum (64c, 65c) disposed between the peak and a propagation angle (64d, 65d) of less than about 60 degrees. In some embodiments, the peak (64a, 65a) is at a propagation angle (64b, 65b) less than about 8, or 6, or 4, or 2, or 1 degrees. In some such embodiments, or in other embodiments, the global minimum (64c, 65c) is disposed between the peak and a propagation angle (64d, 65d) of less than about 60, or 55, or 50, or 45, or 40, or 35 degrees. In some such embodiments, or in other embodiments, the global minimum (64c, 65c) is disposed at an angle greater than about 5, or 10, or 15, or 20 degrees. In some embodiments, the at least one plane includes first (e.g., xz-plane) and second (e.g., x′z-plane; see, e.g., FIG. 12) planes that are both parallel to the thickness direction and make an angle α1 of at least about 30, or 35, or 40, or 45 degrees with each other. In some embodiments, the one or more light diffractive regions 21 includes a plurality of substantially parallel linear diffractive elements 23 extending along a same in-plane first direction (e.g., y-direction) and arranged along a same in-plane orthogonal second direction (e.g., x-direction). In some embodiments, the first plane is substantially parallel to the second direction. In some embodiments, a peak (e.g., 64a and/or 65a) at the propagation angle less than about 10 degrees, has a normalized intensity of at least 1.1, 1.2, 1.2, 1.4, or 1.5. The normalized intensity at this peak can be up to about 2, 1.8, 1.7, or 1.6, for example.

In some embodiments, the display system 300, 305, 310 is such that for substantially mutually orthogonal first (e.g., xz-plane) and second (e.g., yz-plane) planes that are parallel to the thickness direction, and for at least one wavelength (e.g., blue, red, and/or green wavelength(s)) in a visible wavelength range extending from about 420 nm to about 680 nm, a normalized intensity profile (64, 68) of the display system normalized with respect to a comparative intensity profile (66′, 69′) of a comparative display system (e.g., 310′) that has a same construction except that it does not include the one or more light diffractive regions 21, includes: in the first plane, a global minimum 64c at a propagation angle 64d of less than about 60 degrees; and in the second plane, a magnitude of greater than about 1, or 1.05, or 1.1, or 1.15, or 1.2 for all propagation angles from about zero degrees (e.g., less than about 10, or 8, or 6, or 4, or 2, or 1 degrees) to at least about 40 degrees. In some embodiments, the magnitude is in at least one of these ranges for all propagation angles from about zero degrees to at least about 45, or 50, or 55, or 60, or 65, or 70, or 75, or 80 degrees. For example, in some embodiments, in the second plane, the magnitude is greater than about 1.1 for all propagation angles from about zero degrees to at least about 50 degrees, or the magnitude is greater than about 1.2 for all propagation angles from about zero degrees to at least about 55 degrees or to at least about 60 degrees. For example, the second plane can correspond to a horizontal direction in a television or other display application and a normalized intensity of greater than 1 may be desired in the second plane for a broad range of propagation angles in such applications. In some embodiments, the global minimum 64c is at a propagation angle 64d of less than about 55, or 50, or 45, or 40, or 35, or 30, or 25 degrees. The global minimum 64c can be at a propagation angle 64d of greater than about 5, or 10, or 15, or 20 degrees, for example. In some embodiments, the one or more light diffractive regions 21 includes a plurality of substantially parallel linear diffractive elements 23 extending along a same in-plane first direction (e.g., y-direction) and arranged along a same in-plane orthogonal second direction (e.g., x-direction), where the first and second planes are substantially orthogonal to the respective first and second directions. The diffractive elements 23 can have any of the geometries described elsewhere herein and/or can be arranged in any of the patterns describe elsewhere herein.

### EXAMPLES

OLED display systems generally as illustrated in FIGS. 3 and 8 were modeled using conventional ray tracing techniques. The diffractive gratings were simulated via rigorous coupled wave analysis (RCWA) and the scattering information was then compiled for utilization during the ray trace. The source was modeled as a weak-cavity, bottom-emitting white OLED pixel with microcavity simulation software. In the raytrace the white OLED source was filtered by blue, green, red, and while color filter materials to produce blue, green, red, and white emission, respectively.

FIG. 9 shows plots of light intensity recorded in air as a function of polar angle for emission from blue OLED pixels (peak wavelength of about 460 nm) of a display system generally as schematically illustrated in FIG. 3. The curves 61, 25 and 63 are for the case where there was a light diffractive layer disposed on. and spaced apart by 500 microns in the thickness direction from, the OLED pixels by a material with refractive index of roughly 1.5. All (100% by area in a top view) the light diffractive regions of the light diffractive layer overlapped 100% with the interpixel display regions 13a. There was no overlapping of the diffractive regions of the diffractive layer and the pixel regions 12 or the interpixel regions 13b. The diffractive layer included a one-dimensional (1D) linear grating such that the grating ridges were oriented along the y-direction shown in FIG. 3. The binary rectangular grating included of bottom and top materials (see, e.g., FIG. 7) with refractive indices of approximately 1.5 and 1.85, respectively, and had a pitch of 1200 nm, rectangular ridges with height of 900 nm, and a 60% duty cycle (refractive index ˜1.5 material). The curves 61′, 25′ and 63′ are for a comparative display system that had the same construction as the display system described above except that it did not include the light diffractive layer. The curves 61, 64, and 25 correspond to light emitted in the xz-plane, yz-plane, and a plane parallel to the thickness direction (z-direction) that is rotated 45 degrees from the xz-plane, respectively. In the xz-plane, the peak intensity 62 of the intensity profile was about 0.195 W/sr, the corresponding peak intensity 62′ of the comparative intensity profile was about 0.135 W/sr, the HWHM Wb0 of the intensity profile was about 16 degrees, and the HWHM Wb0′ of the comparative intensity profile Wb0′ was about 51.5 degrees. In the yz-plane, the HWHM Wb90′ of the intensity profile was about 45 degrees, and the HWHM Wb90′ of the comparative intensity profile Wb0′ was about 48.5 degrees.

FIG. 11 is for the same display structure and layout described for FIG. 10 except that the intensity being recorded in air as a function of polar angle is for emission from green OLED pixels (peak wavelength of about 550 nm) instead of the blue OLED pixels of FIG. 11. Here, in the xz-plane, the peak intensity 82 with the diffractive layer was 0.196 W/sr and the peak intensity 82′ of the comparative intensity profile was 0.128 W/sr.

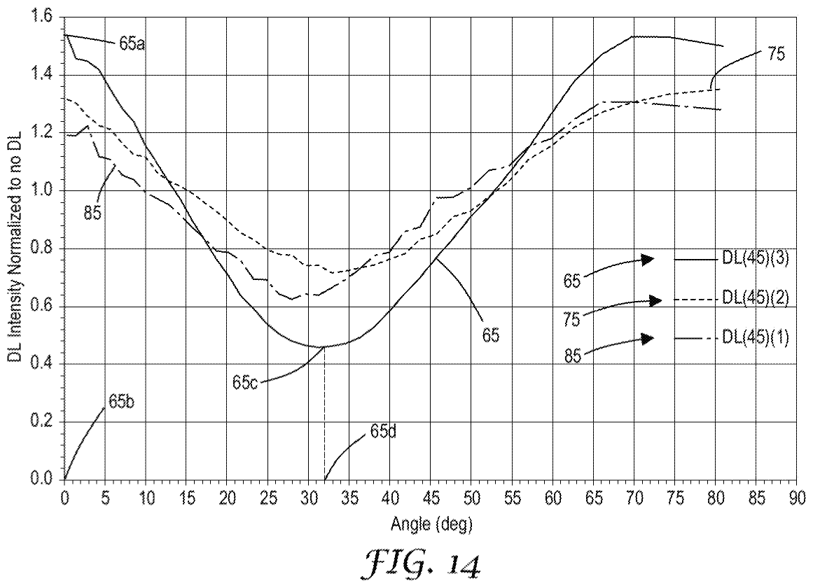

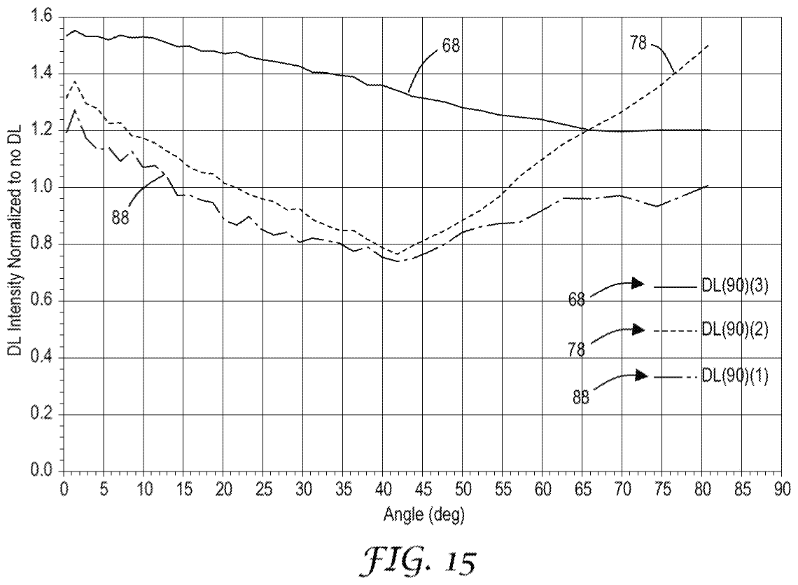

FIG. 13 shows normalized intensity recorded in air as a function of polar angle for emission from green OLED pixels for three different display structure cases. In each case, the intensity recorded for a given display structure and layout with the diffractive layer (DL) present was normalized with respect to comparative intensities of corresponding comparative display systems where the diffractive layer was removed. All data in this plot is for intensity recorded along the xz-plane (the only transverse component is perpendicular to the gratings). (The curves are labeled as DL(angle)(i) where angle is 0 (FIG. 13), 45 (FIG. 14), or 90 (FIG. 15) degrees relative to the xz-plane and i (1, 2, or 3) represents three sample layouts as described further below). The curve 64 shows normalized intensity for the display layout schematically illustrated in FIG. 3 with the modeling parameters as described above for FIG. 10 and with emission from the green OLED pixels of FIG. 11. The curve 74 shows normalized intensity for the display layout schematically illustrated in FIG. 8 where the pixels were arranged on a square lattice with a 40 micron pitch and had a pixel size of 20 micron square and where the grating pattern covered regions between the pixels. Here, the diffractive layer was spaced apart from the OLED pixels in the thickness direction by 25 microns. The diffractive layer included a binary rectangular grating with bottom and top materials having refractive indices of approximately 1.45 and 1.8, respectively (see, e.g., FIG. 7). The grating ridges were oriented such that they are parallel to the y-direction and the grating had a pitch of 1200 nm, ridge height of 1000 nm, and a duty cycle of 70% (refractive index ˜1.45 material). The curve 84 is for a case corresponding to a single 20 micron square pixel with the grating patten forming a 10 micron frame around the pixel. The diffractive layer spacing from the OLED pixel was 25 microns and the grating structure was the same as that described for curve 74. Curve 64 had a global minimum 64c at a propagation angle 64d of about 23 degrees.

FIG. 14 shows normalized intensity for a display system that is equivalent to the cases described for FIG. 13 where all data recorded here is for intensity within a plane parallel to the thickness direction that is rotated 45 degrees from the xz-plane. Here, curve 65 is for the same display system as described for curve 64, curve 75 is for the same display system as described for curve 74, and curve 85 is for the same display system as described for curve 84. Curve 65 had a global minimum 65c at a propagation angle 65d of about 32 degrees.

FIG. 15 shows normalized intensity for a display system that is equivalent to the cases described for FIG. 13 where all data recorded here is for intensity within the yz-plane. Here, curve 68 is for the same display system as described for curve 64, curve 78 is for the same display system as described for curve 74, and curve 88 is the same display system as described for curve 84. Curve 68 shows a normalized intensity greater than unity for all polar angles between 0 and 80 degrees which means the intensity with the diffractive layer present is greater than the comparative case in the yz-plane for all polar angels up to 80 degrees.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially” with reference to a property or characteristic is not otherwise clear to one of ordinary skill in the art in the context in which it is used and described in the present description and when it would be clear to one of ordinary skill in the art what is meant by an opposite of that property or characteristic, the term “substantially” will be understood to mean that the property or characteristic is exhibited to a greater extent than the opposite of that property or characteristic is exhibited.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations, or variations, or combinations of the specific embodiments discussed herein. Therefore, it is intended that this disclosure be limited only by the claims and the equivalents thereof.

1-15. (canceled)

16. A display system comprising:
a display region configured to form an image thereacross for viewing by a viewer and comprising a light emitting region configured to emit light and a light non-emitting region not configured to emit light; and
a light diffractive layer configured to be between the viewer and the display region and disposed substantially parallel to, and spaced apart along a thickness direction of the display system from, the display region, the light diffractive layer comprising a light diffractive region configured to diffract light and a light non-diffractive region not configured to diffract light, the light diffractive and non-diffractive regions of the light diffractive layer aligned, and substantially coextensive in length and width, with the respective light non-emitting and emitting regions of the display region,
wherein light exiting the display system and light exiting a comparative display system having a same construction as the display system except that it does not include the light diffractive layer have respective intensity and comparative intensity profiles as a function of light propagation angle, such that for at least one wavelength in a visible wavelength range extending from about 420 nm to about 680 nm and for at least a first plane that is parallel to the thickness direction:
a peak intensity of the intensity profile is greater than a peak intensity of the comparative intensity profile by at least 10%; and
a half width at half maximum (HWHM) of the intensity profile is smaller than a HWHM of the comparative intensity profile by at least 10 degrees.

17. The display system of claim 16, wherein an average spacing between the light diffractive layer and the display region is greater than about 10 microns and less than about 5000 microns.

18. The display system of claim 16, wherein the light emitting region is configured to emit:
an emitted first cone of light that comprises an emitted first central light ray propagating along an emitted first direction, the emitted first cone of light being incident on the non-diffractive, but not the diffractive, region of the light diffractive layer and at least a portion of the emitted first cone of light being transmitted by the non-diffractive region of the light diffractive layer as a transmitted first cone of light having a transmitted first central light ray propagating along a transmitted first direction within about 10 degrees of the emitted first direction; and
an emitted second cone of light that comprises an emitted second central light ray propagating along an emitted second direction making an angle of greater than about 10 degrees with the emitted first direction, the emitted second cone of light being incident on the diffractive, but not the non-diffractive, region of the light diffractive layer and at least a portion of the emitted second cone of light being diffractively transmitted by the diffractive region of the light diffractive layer as a diffracted second cone of light having a diffracted second central light ray propagating along a diffracted second direction making an angle of less than about 10 degrees with the emitted first direction.

19. The display system of claim 18, wherein at least 50% of the emitted first cone of light is transmitted by the non-diffractive region of the light diffractive layer.

20. The display system of claim 18, wherein at least 80% of the emitted first cone of light is transmitted by the non-diffractive region of the light diffractive layer.

21. The display system of claim 18, wherein at least 5% of the emitted second cone of light is diffractively transmitted by the diffractive region of the light diffractive layer.

22. The display system of claim 18, wherein at least 35% of the emitted second cone of light is diffractively transmitted by the diffractive region of the light diffractive layer.

23. The display system of claim 16, wherein the light diffractive region comprises a plurality of substantially parallel linear diffractive elements extending along a same in-plane first direction and arranged along a same in-plane orthogonal second direction, the first direction orthogonal to the first plane.

24. The display system of claim 16, wherein in a second plane that is orthogonal to the first plane and the thickness direction, and for the at least one wavelength, a HWHM of the intensity profile in smaller than a HWHM of the comparative intensity profile.

25. The display system of claim 16, wherein for the at least one wavelength, for the at least the first plane, and for each propagation angle in an angular range of from at most 10 degrees to at least 50 degrees, the intensity profile has a magnitude greater than a magnitude of the comparative intensity profile.

26. A display system comprising:
one or more light emitting regions configured to emit light and one or more light non-emitting regions not configured to emit light and substantially co-planar with the one or more light emitting regions; and
one or more light diffractive regions disposed on, and spaced apart along a thickness direction of the display system from, the one or more light non-emitting regions, such that in a top plan view, the one or more light diffractive regions cover more than 60% of the one or more light non-emitting regions and less than 40% of the one or more light emitting regions, at least some light obliquely emitted by the one or more light emitting regions exiting the display system after being diffractively transmitted by the one or more light diffractive regions,
such that in each plane of at least one plane parallel to the thickness direction, and for at least one wavelength in a visible wavelength range extending from about 420 nm to about 680 nm, a normalized intensity profile of the display system normalized with respect to a comparative intensity profile of a comparative display system that has a same construction except that it does not include the one or more light diffractive regions, comprises a peak at a propagation angle of less than about 10 degrees and a global minimum disposed between the peak and a propagation angle of less than about 60 degrees.

27. The display system of claim 26, wherein the at least one plane comprises first and second planes that are both parallel to the thickness direction and make an angle of at least about 30 degrees with each other.

28. The display system of claim 27, wherein the one or more light diffractive regions comprises a plurality of substantially parallel linear diffractive elements extending along a same in-plane first direction and arranged along a same in-plane orthogonal second direction, the first plane being substantially parallel to the second direction.

29. A display system comprising:
one or more light emitting regions configured to emit light and one or more light non-emitting regions not configured to emit light and substantially co-planar with the one or more light emitting regions; and
one or more light diffractive regions disposed on, and spaced apart along a thickness direction of the display system from, the one or more light non-emitting regions, such that in a top plan view, the one or more light diffractive regions cover more than 60% of the one or more light non-emitting regions and less than 40% of the one or more light emitting regions, at least some light obliquely emitted by the one or more light emitting regions exiting the display system after being diffractively transmitted by the one or more light diffractive regions,
such that for substantially mutually orthogonal first and second planes that are parallel to the thickness direction, and for at least one wavelength in a visible wavelength range extending from about 420 nm to about 680 nm, a normalized intensity profile of the display system normalized with respect to a comparative intensity profile of a comparative display system that has a same construction except that it does not include the one or more light diffractive regions, comprises:
in the first plane, a global minimum at a propagation angle of less than about 60 degrees; and
in the second plane, a magnitude of greater than about 1 for all propagation angles from about zero degrees to at least about 40 degrees.

30. The display system of claim 29, wherein the one or more light diffractive regions comprises a plurality of substantially parallel linear diffractive elements extending along a same in-plane first direction and arranged along a same in-plane orthogonal second direction, the first and second planes being substantially orthogonal to the respective first and second directions.
